(19) United States
(12) Patent Application Publication
(10) Pub. No.: US 2025/0391644 A1
(43) Pub. Date: Dec. 25, 2025

(54) Insulated Dual Liner for Plasma Processing Chamber

(71) Applicant: Applied Materials, Inc., Santa Clara, CA (US)

(72) Inventors: Dongjiang WANG, Chengdu (CN); Longjie YU, Chengdu (CN); Ping ZHENG, Chengdu (CN); Lin LUO, Chengdu (CN); Song HUANG, Shanghai (CN); Chenyu WANG, Shanghai (CN)

(21) Appl. No.: 18/962,323

(22) Filed: Nov. 27, 2024

(30) Foreign Application Priority Data
Jun. 5, 2024 (WO) PCT/CN2024/097475

(51) Int. Cl. H01J 37/32

(52) U.S. Cl. CPC H01J 37/32495; H01J 37/32862; H01J 37/32082; H01J 2237/334

(57) ABSTRACT

Methods and apparatus for substrate processing using a dual liner for a substrate processing chamber having a chamber wall, the dual liner comprising: a conductive outer liner configured to be fixed to the substrate processing chamber and extend about an inner side of the chamber wall; and a conductive inner liner surrounded by the outer liner and coupled thereto, the inner liner electrically insulated from the outer liner.

### CROSS-REFERENCE TO RELATED APPLICATIONS

This application is a continuation of International Patent Application PCT/CN2024/097475, filed Jun. 5, 2024, the entire contents of which are incorporated herein by reference.

### FIELD

Embodiments of the present disclosure generally relate to a substrate processing, and more particularly, to a liner for substrate processing chambers.

### BACKGROUND

Plasma dry etching is used in semiconductor manufacture to remove plastic or other semiconductor material using plasma inside an etch chamber. Inside the etch chamber, a liner may be provided to confine the plasma, modulate the gas flow to form a uniform gas flow field inside the chamber, and screen the plasma to limit or prevent any damage and/or polymer deposition onto the chamber wall.

The plasma dry etching process may be affected by the condition of surfaces in the chamber, such as the surface of the liner. Coating and non-coating in situ-chamber-cleaning/coating (ICC) are procedures that are often performed as preventive maintenance in an etch chamber to help maintain chamber conditions over time to mitigate process shift from substrate to substrate. Non-coating ICC is often used to clean materials, such as polymer, that may be stuck to the liner and other surfaces inside the chamber. Coating ICC may be used to coat materials (e.g., SiO or polymer) on the liner or other surfaces inside the etch chamber after cleaning to prepare for processing additional substrates.

Often, the liner is grounded to screen the plasma from the chamber wall. Since the liner is grounded, there is no plasma coupling between the liner and the plasma. The inventors have observed that during substrate processing or coating/non-coating ICC, the plasma is mostly confined above a substrate support. In the case of coating/non-coating ICC, a high-pressure step is often used to force the plasma to extend to the liner, but the cleaning and coating efficiency is low. In the case of substrate processing, the plasma may not extend uniformly to the edge of the substrate, which may inhibit meeting desired edge uniformity process requirements.

Thus, methods and apparatus are proposed that can extend the plasma to the liner to improve cleaning and coating efficiency as well as process edge uniformity.

### SUMMARY

Methods and apparatus for substrate processing are provided herein. In some embodiments, a dual liner is provided for a substrate processing chamber having a chamber wall, the dual liner comprising: a conductive outer liner configured to be fixed to the substrate processing chamber and extend about an inner side of the chamber wall; and a conductive inner liner surrounded by the outer liner and coupled thereto, the inner liner electrically insulated from the outer liner.

In some embodiments, a substrate processing chamber includes: a substrate support configured to support a substrate; a chamber wall surrounding the substrate support and defining a processing volume; and a dual liner coupled to the chamber wall and surrounding the substrate support, the dual liner comprising: an outer liner fixed to the substrate processing chamber and extending about an inner side of the chamber wall; and an inner liner surrounded by the outer liner and coupled thereto, the inner liner electrically insulated from the outer liner.

In some embodiments, a method of substrate processing in a substrate processing chamber in accordance with the present disclosure includes: forming a plasma in the substrate processing chamber between the inner liner and the substrate support; and applying RF bias to the inner liner while grounding the outer liner.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 shows a schematic of a substrate processing chamber in accordance with some embodiments of the present disclosure.

FIGS. 2A-2C are exploded views of a portion A in FIG. 1 of a dual liner of the substrate processing chamber in accordance with some embodiments of the present disclosure.

FIG. 3 shows a method of substrate processing in accordance with some embodiments of the present disclosure.

FIG. 4A shows the substrate processing chamber of FIG. 1 during a substrate processing method in accordance with some embodiments of the present disclosure.

FIG. 4B shows an exploded view of a portion B in FIG. 4A.

FIGS. 5A-5E show the substrate processing chamber of FIG. 1 during a substrate processing method in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a method and apparatus for substrate processing are provided herein that use a dual liner with RF bias to extend plasma to the dual liner. As discussed in greater detail herein, by applying RF bias, during non-coating/coating ICC, the cleaning and coating efficiency increase (in comparison to not applying RF bias) to improve throughput of substrate processing. Moreover, during substrate processing, the RF bias may be tuned to tilt the plasma around the substrate, thereby improving substrate edge uniformity.

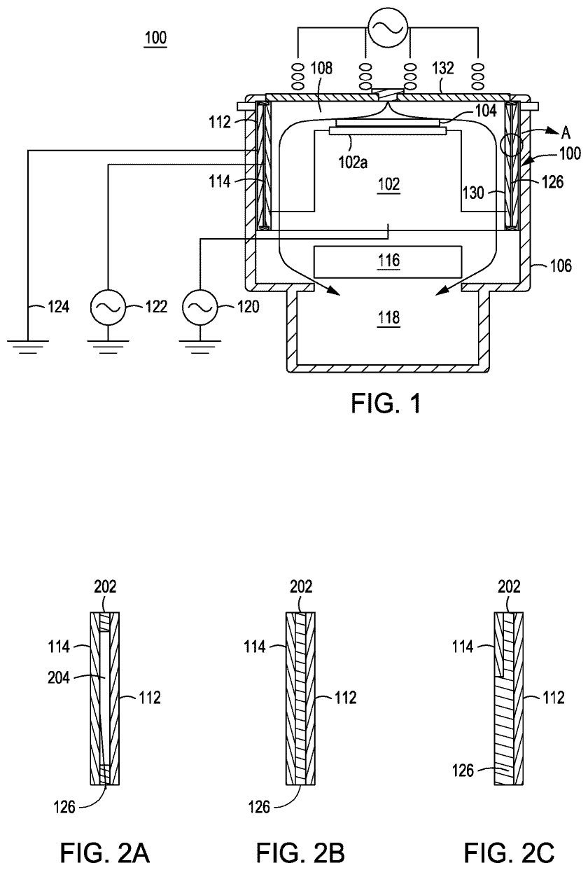

FIG. 1 shows a schematic of a substrate processing chamber 100 in accordance with some embodiments of the present disclosure. In some embodiments, the substrate processing chamber 100 may be an inductive coupled plasma (ICP) chamber. In some embodiments, the substrate processing chamber 100 may be a capacitive coupled plasma (CCP) chamber. The substrate processing chamber 100 may be configured for various processes such as etching (e.g., plasma dry etching) processes or deposition. In some embodiments, and as shown in FIG. 1, the substrate processing chamber 100 may include a substrate support 102 configured to support a substrate 104, and a chamber wall 106 surrounding the substrate support 102 and defining a processing volume 108. In some embodiments, the substrate support 102 may have an electrostatic chuck (ESC) 102a configured to support and retain the substrate 104 during substrate processing. The substrate processing system may include a lid 132.

The substrate processing chamber 100 may also include a dual liner 110 coupled to the chamber wall 106 and surrounding the substrate support 102. The dual liner 110 may include an outer liner 112 fixed to the substrate processing chamber 100 and extending about an inner side of the chamber wall 106. The dual liner 110 may also include an inner liner 114 surrounded by the outer liner 112 and connected thereto. The inner liner 114 has an inner surface 130 facing the substrate support 102. The inner liner 114 may be electrically insulated from the outer liner 112 by an insulator 126.

In some embodiments, and as shown in FIG. 1, the substrate processing chamber 100 may include a valve 116 to balance gas flow (denoted by arrows around the substrate support 102) in the substrate processing chamber 100. Also, in some embodiments, and as shown in FIG. 1, the substrate processing chamber 100 may include a pump 118 configured to evacuate the processing volume 108 and directing gas flow from the processing volume 108 down around the substrate support 102 and out of the substrate processing chamber 100.

At least one of the outer liner 112 or the inner liner 114 may be conductive. In some embodiments, at least one of the outer liner 112 or the inner liner 114 is comprised of metal, such as aluminum and stainless steel. At least one of the outer liner 112 or the inner liner 114 may be coated with a dielectric coating, such as a ceramic coating or a non-conductive oxide (e.g., yttrium oxide or yttrium oxide and silicon). The dielectric coating may also provide surface protection for the outer liner 112 and/or the inner liner 114.

In some embodiments, and as shown in FIG. 1, the substrate processing chamber 100 may include an RF power supply 120 connected to the substrate support 102, which may be configured as a cathode. In some embodiments, and as shown in FIG. 1, the substrate processing chamber 100 may include an RF power supply 122 coupled to the inner liner 114. The outer liner 112 may be coupled to ground 124. In some instances during substrate processing, the inner liner 114 and/or the substrate support 102 can be grounded. In some embodiments, the inner liner 114 may be grounded independently of the substrate support 102. In some embodiments, the RF power supplies 120 and 122 may be configured to independently ground the inner liner 114 and the substrate support 102.

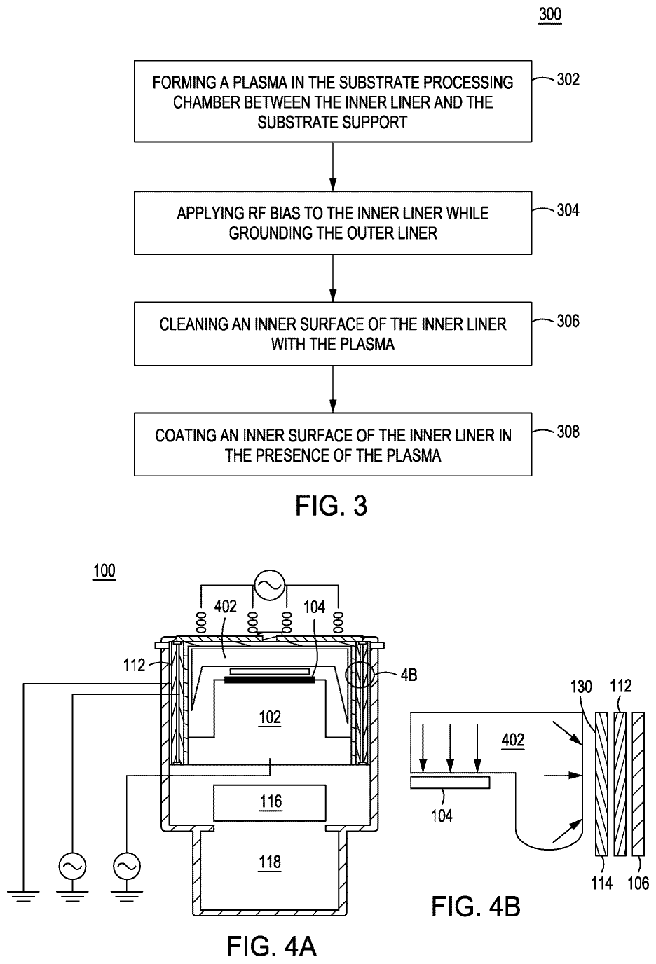

In some embodiments, and as shown in FIGS. 2A-2C, the inner liner 114 may be spaced (e.g., radially) from the outer liner 112 by the insulator 126. In some embodiments, and as shown in FIG. 2A, the insulator 126 may include at least one of a solid portion 202 or a gap 204 (e.g. air gap). The solid portion 202 may include ceramic or other insulative materials that are process compatible with substrate processing steps being performed in the substrate processing chamber 100. In at least some embodiments, the inner liner 114 may at least partially cover the outer liner 112. For example, FIG. 2B shows an embodiment of the dual liner 110 where the inner liner 114 fully covers the outer liner 112, and FIG. 2C shows an embodiment of the dual liner 110 where the inner liner 114 partially covers the outer liner 112.

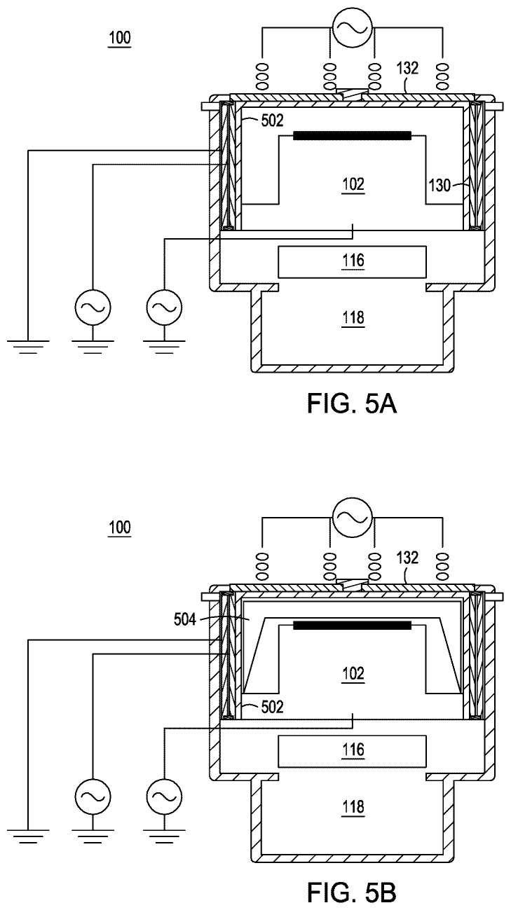

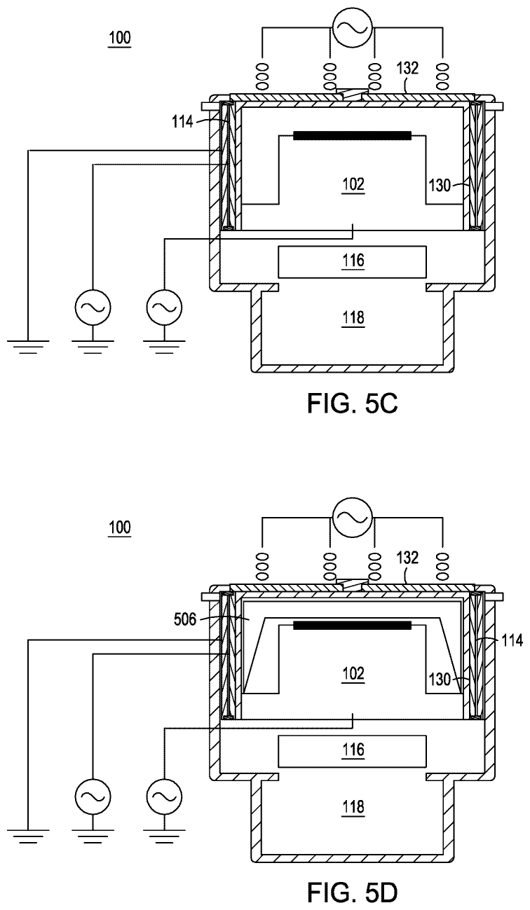

FIG. 3 shows a method 300 of substrate processing in accordance with some embodiments of the present disclosure. In some embodiments, at block 302, the method 300 may include forming a plasma in a substrate processing chamber, such as the plasma 402 formed in the substrate processing chamber 100 shown in FIG. 4A, between the inner liner 114 and the substrate support 102. In some embodiments, forming the plasma may include flowing a plasma forming gas (e.g., TiCl, ClF₃, perfluorocarbons (PFC)) into the processing volume 108.

In some embodiments, at block 304, the method 300 may include applying RF bias to the inner liner 114 while grounding the outer liner 112, as shown in FIG. 4A. The outer liner 112 may be grounded to screen plasma from the chamber wall 106. The power for the RF bias may be supplied by the RF power supply 122 connected to the inner liner 114. In some embodiments, the applied RF bias may be less than 500 W. In some embodiments, the pulse frequency may be less than 10 kHz. In some embodiments, the RF bias may be applied at a duty cycle of 10-100%. As shown in FIG. 4B, the applied RF bias extends the plasma 402 outward toward inner liner 114 and down below the substrate 104 along the inner surface 130 of the inner liner 114. The applied RF bias can be tuned to tilt the plasma 402 around the edge of the substrate support 102 to improve substrate edge uniformity during substrate processing.

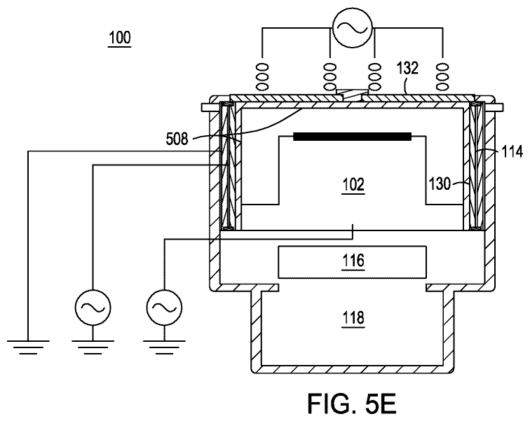

FIG. 5A shows the substrate processing chamber 100 after processing the substrate 104 shown in FIGS. 4A and 4B. In FIG. 5A, the substrate 104 may be removed from the substrate processing chamber 100 prior to cleaning. In FIG. 5A, deposits 502 of material (e.g., polymer from etch processing) may be stuck to the inner surface 130 of the inner liner 114 and/or one or more surfaces of the substrate processing chamber 100 (e.g., the lid 132).

In some embodiments, at block 306, the method 300 may include cleaning the inner surface 130 of the inner liner 114 with plasma. FIG. 5B shows the substrate processing chamber 100 during a non-coating ICC process where RF bias is applied to the inner liner 114 while a plasma 504 is formed to clean the inner surface 130 of the inner liner 114 and/or the one or more surfaces of the substrate processing chamber 100. The plasma 504 may be selected to clean the deposits 502. FIG. 5C shows the substrate processing chamber 100 after the ICC cleaning process in FIG. 5B is completed and the deposits 502 are removed.

In some embodiments, at block 308, the method 300 may include coating the inner surface 130 of the inner liner 114 in the presence of plasma. FIG. 5D shows the substrate processing chamber 100 during a coating ICC process where RF bias is applied to the inner liner 114 while a plasma 506 is formed to coat the inner surface 130 of the inner liner 114 (e.g., with silicon oxide or polymer) as well as one or more surfaces of the substrate processing chamber 100. The plasma 506 may be selected to coat the inner surface 130 of the inner liner 114 as well as one or more surfaces of the substrate processing chamber 100. FIG. 5E shows the substrate processing chamber 100 after coating is complete in FIG. 5D where a coating 508 is on the inner surface 130 of the inner liner 114 and the lid 132. As a result of applying the RF bias to the inner liner 114, the coating applied to the inner liner 114 and to surfaces of the substrate processing chamber 100 may also be more dense and, consequently, more durable than coatings applied without the RF bias applied to the inner liner 114. Thus, the coating ICC process does not need to be performed after every cleaning ICC process, which may further advantageously reduce time needed for preventive maintenance.

After performing the ICC cleaning and/or coating processes, the chamber may be used to resume substrate processing, such as shown in FIG. 4A. Therefore, the method 300 described herein may include a coating ICC process and/or non-coating ICC process, which may be performed periodically or as needed between processing of one or more substrates 104 in the substrate processing chamber 100.

By applying RF bias to the inner liner 114 while forming the plasma in the substrate processing chamber 100, the cleaning rate and coating rate may increase in comparison to the cleaning rate and coating rate when RF bias is not applied, which is beneficial for reducing downtime of the chamber and improving substrate processing throughput of the chamber. As a result of improving the cleaning efficiency of the inner liner 114, the electrostatic chuck 102a may experience reduced exposure to plasma, which may be beneficial for protecting and preserving the electrostatic chuck |102a. Also, as a result of improving coating efficiency, the electrostatic chuck 102a may be subject to less contact with coating or particulate material, which may be a source of particle contamination during substrate processing (e.g., particle contamination during dechucking). Additionally, as a result of applying the RF bias to the inner liner 114, the coating applied to the inner liner 114 and to surfaces of the substrate processing chamber 100 may also be more durable, thereby potentially reducing time needed for preventive maintenance. Finally, as noted above, applying RF bias may also improve substrate edge uniformity, thereby potentially improving production yields.

While the foregoing is directed to embodiments of the present disclosure, other and further embodiments of the disclosure may be devised without departing from the basic scope thereof.

1. A dual liner for a substrate processing chamber having a chamber wall, the dual liner comprising:
a conductive outer liner configured to be fixed to the substrate processing chamber and extend about an inner side of the chamber wall; and
a conductive inner liner surrounded by the outer liner and coupled thereto, the inner liner electrically insulated from the outer liner.

2. The dual liner of claim 1, wherein the inner liner is radially spaced from the outer liner.

3. The dual liner of claim 1, wherein the inner liner at least partially covers the outer liner.

4. The dual liner of claim 1, wherein the inner liner is electrically insulated from the outer liner by an insulator having at least one of a solid portion or a gap.

5. The dual liner of claim 1, wherein at least one of the outer liner or the inner liner is comprised of at least one of aluminum or stainless steel.

6. The dual liner of claim 1, wherein at least one of the inner liner or the outer liner is coated with a dielectric.

7. The dual liner of claim 1, wherein at least one of the inner liner or the outer liner is coated with at least one of yttrium oxide or silicon.

8. A substrate processing chamber, comprising:
a substrate support configured to support a substrate;
a chamber wall surrounding the substrate support and defining a processing volume; and
a dual liner according to claim 1 coupled to the chamber wall and surrounding the substrate support.

9. The substrate processing chamber of claim 8, wherein the inner liner is electrically insulated from the outer liner by an insulator having at least one of a solid portion or a gap.

10. The substrate processing chamber of claim 8, wherein at least one of the outer liner or the inner liner is comprised of at least one of aluminum or stainless steel.

11. The substrate processing chamber of claim 8, wherein at least one of the inner liner or the outer liner is coated with a dielectric.

12. The substrate processing chamber of claim 8, wherein at least one of the inner liner or the outer liner is coated with at least one of yttrium oxide or silicon.

13. The substrate processing chamber of claim 8, further comprising an RF power supply coupled to the inner liner, and wherein the outer liner is grounded.

14. The substrate processing chamber of claim 13, wherein the RF power supply is configured to selectively ground the inner liner.

15. A method of substrate processing in a substrate processing chamber having a substrate support and a chamber wall about the substrate support, the method comprising:
forming a plasma in the substrate processing chamber between an inner liner of a dual liner and the substrate support, wherein the dual liner is coupled to the chamber wall; and
applying RF bias to the inner liner while grounding an outer liner of the dual liner, the outer liner surrounding the inner liner.

16. The method of claim 15, wherein the applied RF bias is less than 500 W.

17. The method of claim 15, wherein the RF bias has a pulse frequency less than 10 kHz.

18. The method of claim 15, wherein the RF bias is applied at a duty cycle of 10-100%.

19. The method of claim 15, further comprising cleaning an inner surface of the inner liner with the plasma.

20. The method of claim 15, further comprising coating an inner surface of the liner in the presence of the plasma.
